(19) United States
(12) Patent Application Publication
(10) Pub. No.: US 2008/0012639 A1
(43) Pub. Date: Jan. 17, 2008

(54) Dual Mode Audio Amplifier

(75) Inventor: Frank Kamiel Irena Mels, Brugge (BE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/573,364

(22) PCT Filed: Jul. 25, 2005
(86) PCT No.: PCT/IB05/52493

§ 371 Date: Feb. 7, 2007

(30) Foreign Application Priority Data
Aug. 12, 2004 (EP) 04103907.4

(51) Int. Cl. H03F 1/34; H03F 1/30; H03F 3/30; H03F 1/32

(52) U.S. Cl. 330/251; 330/293

(57) ABSTRACT

A dual mode power amplifier for an audio signal operates in linear mode at lower levels of the audio signal and in switched mode (Class D) at higher levels of the audio signal.

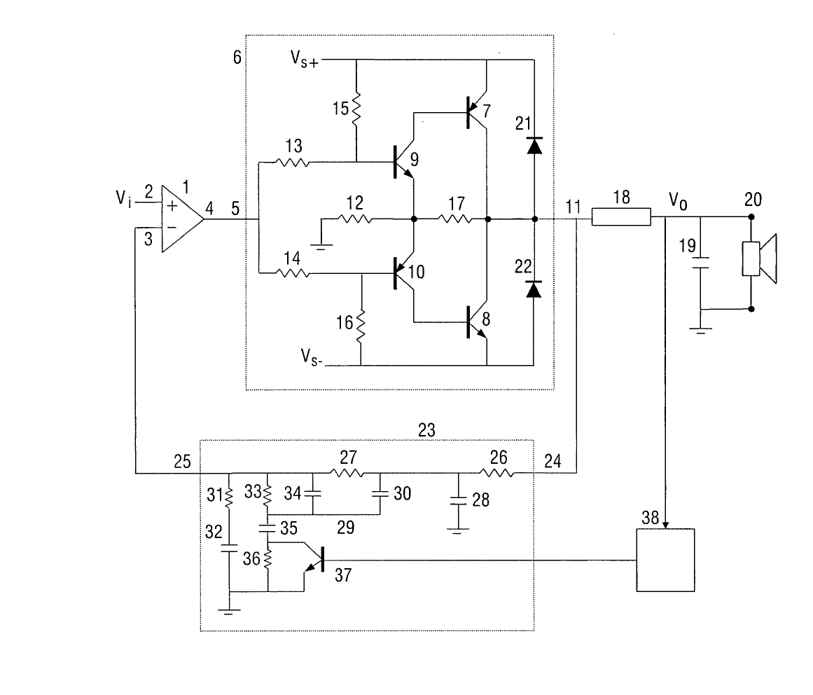

The invention relates to a dual mode audio amplifier comprising a single power output stage for linear (e.g. Class A/AB/B) operation in a first mode and for switched (e.g. Class D) operation in a second mode and comprising mode switching means for switching the operation of the power output stage between the two modes.

It is known that Class D power output stages have high power efficiency but on the other hand give rise to considerable interferences. The Class D amplifier oscillates with a switching frequency that is far higher than the highest audio frequency (e.g. 500 kHz). The strongly alternating load of the power supply results in a ripple on the supply line of the Class D amplifier and through the supply line this ripple interferes with the operation of other stages of the equipment. In US 2003/0194970 A1 the problem is encountered that the Class D amplifier, switching in the 100 kHz to 2 MHz range, generates harmonics which interfere with the AM-radio reception. To counter this problem the audio amplifier of this prior art is operated in Class D only at FM-reception, while at AM-reception the audio amplifier is biased to operate in linear mode such as Class AB.

A disadvantage of this prior art amplifier is that the output stage, because of its linear operation at AM-reception, still has to be able to dissipate large powers and that large output transistors and expensive heat sinks are necessary to handle the large power dissipation. Moreover, at FM reception, the ripple caused by the Class D operation, gives other kinds of interferences such as rattle, interference with the switching frequency in other channels (in case of more than 1 audio channel) or switch mode power supplies, third harmonic distortion, noise and inferior channel separation of the left and right channels in stereo amplifiers.

It is an object of the present invention to provide an audio amplifier that reduces the abovementioned problems. The invention is defined by the independent claims. The dependent claims define advantageous embodiments. In the dual mode audio amplifier of the present invention the mode switching means are arranged to switch the power output stage in the first mode at lower levels, for example below a first level, of the audio signal and to switch the power output stage in the second mode at higher levels, for example above a second level, of the audio signal. In practice the mode switching may comprise hysteresis so that at intermediate levels between, for example, the first and second levels of the audio signal the mode remains unaltered with respect to the previously active mode, the first and the second level may be the same level, however, if hysteresis is desired then the second level should be higher than the first level.

The invention is based on the following consideration: At the lower signal levels, for instance at output powers up to about 1 watt or the maximum possible output power with the chosen output stage without the use of a heat sink, the amplifier operates in the linear mode, preferably Class AB. At these lower powers the amplifier is free from the artifacts that are inherent to Class D operation, such as the ripple on the supply line whereas most of the other artifacts mentioned above, such as third harmonic distortion, poor channel separation and signal to noise ratio are sufficiently low. Usually this situation occurs in 98% of the time. From the moment higher output power is needed the amplifier switches to the Class D mode. In this state the artifacts mentioned above do exist but are less audible because of the higher produced sound output. The sound output power is now much higher than the artifacts and will substantially mask these artifacts for the human ear. In this way costly printed circuit boards, heat sinks, high-power output stages and higher power consumption, which would normally be required when operating high-level signals in Class AB, are avoided.

It may be noted that it is already known from the paper “High Efficiency Audio Power Amplifiers, design and practical use” by Ronan van der Zee, Academic Publication on line of University of Twente, the Netherlands, 1999, ISBN: 90-36512875”, to combine linear and Class D audio amplifiers to avoid the disadvantages of each of them. However these are expensive solutions because two power output stages are needed instead of the single power output stage of the present invention.

It may also be noted that U.S. Pat. No. 4,441,081 discloses a servo amplifier with a power output stage that operates in Class A when the servo system is in “following” mode and in Class D when it is in the “seeking” mode. However, the requirements to be set to audio amplifiers, e.g. the frequency range of the signal to be amplified, and the artifacts that have to be avoided in audio amplifiers, e.g. the transients that have to be 60-80 db lower than the signal, are orders of magnitude different from those occurring in servo amplifiers.

In the audio amplifier of the present invention it is of importance to (substantially) avoid audible glitches (transients) at the moments the amplifier is switched from one mode to the other. Such glitches are practically unavoidable when the mode switching means are situated in the signal path of the amplifier, as is done in the above mentioned US 2003/0194970. The dual mode audio amplifier according to the present invention may be further characterized by a signal path comprising said power output stage and a feedback path bridging at least part of the signal path and/or that the mode switching means are provided in said feedback path.

In practice the audio amplifier according to the invention may comprise in its signal path the cascade of an operational amplifier, the power output stage and a Class D type LC output filter in that order. In a first configuration of such audio amplifier an inverting power output stage is used and the mode switching means are arranged to feed back either the output signals of the power output stage in a first mode or the input signals of the power output stage to an input of the operational amplifier in a second mode, thereby making use of the inversion of the power stage to switch between negative feedback (in the first mode) and positive feedback with its resultant oscillation in the second mode. In a second configuration the mode switching means feed back either the input signals of the LC output filter in the first mode or the output signals of this filter to an input of the operational amplifier in the second mode, thereby using the phase shift of the LC output filter to change the feedback from negative to positive feedback and vice versa.

A third configuration of the dual mode audio amplifier according to the invention, that is preferred because of its robust operation, is characterized in that the feedback path comprises low pass filtering means passing the audio frequency band and phase shifting frequencies above said audio frequency band and in that the mode switching means are arranged to change the amount of phase shift of said frequencies above the audio frequency band. In the audio frequency band the transfer of the low pass filtering means is as flat as reasonably possible resulting in a flat audio signal transfer of the whole amplifier both in the Class AB mode and in the Class D mode. The mode switching means are substantially operative at frequencies above the audio frequency band. The function of the mode switching means is to change the phase characteristic of the feedback path so as to change the negative feedback in the first (Class AB) mode to a positive feedback in the second (Class D) mode.

As noticed earlier, the above-described arrangement has a favorable suppression of the transients occurring at the instants of mode switching. A still better transient suppression is obtained when, according to a further characteristic of the invention, DC-blocking means to prevent DC-potential occurring across the mode switching means are provided. Any DC-voltage across the mode switching means, when open, would result in a DC-transition and a resulting audible transient when the mode switching means are closed or opened. By using DC-free mode switching means these transients are effectively avoided. With the measures described above the transient-suppression is so effective that, when for instance amplifying a large sine wave, it is possible to switch the amplifier in the first (linear) mode during the zero-crossings of the sine wave and in the second (oscillating) mode during the tops of the sine wave.

In a dual mode audio amplifier according to the present invention some problems, such as increased transient sensibility, can be traced back to DC-offsets e.g. in the operational amplifier which usually precedes the power output static. In dual mode audio amplifiers, in which the transfer of the feedback path is substantially lower than 1 for the audio frequency band such problems can be minimized when the transfer of the feedback path is 1 for DC-voltage. This measure prevents that the said DC-offset is amplified in the audio amplifier.

The invention will be described with reference to the accompanying figure, which shows an example of a dual mode audio amplifier according to the invention.

The audio amplifier comprises an operational amplifier 1 having a non-inverting input terminal 2, an inverting input terminal 3 and an output terminal 4. The non-inverting input terminal 2 is arranged to receive an audio signal Vᵢ that is amplified in the operational amplifier and then applied to a signal input terminal 5 of a power output stage 6.

The output stage 6 comprises a PNP-NPN pair of output transistors 7, 8 that is driven by an NPN-PNP pair of driver transistors 9, 10. The emitter electrodes of the Output transistors 7 and 8 are connected to positive and negative supply voltages Vₛ₊ and Vₛ₋. respectively, the collector electrodes of the output transistors 7 and 8 are connected to each other and to an output terminal 11 of the stage 6 and the base electrodes of the output transistors 7 and 8 are respectively connected to the collector electrodes of the driver transistors 9 and 10. The emitter electrodes of the driver transistors are connected through a common emitter resistor 12 to ground and the base electrodes of these transistors are respectively connected through resistors 13 and 14 to the input terminal 5 of the stage 6. A biasing resistor 15 is connected between the positive supply voltage Vₛ₊ and the base electrode of the transistor 9 and a biasing resistor 16 is connected between the negative supply voltage Vₛ₋ and the base electrode of transistor 10. A resistor 17 connected between the interconnected collector electrodes of the output transistors 7 and 8, and the interconnected emitter electrodes of the driver transistors 9 and 10 provides a negative feedback of the two transistor stages.

The output terminal 11 of the power output stage 6 is connected through an inductor 18 to a capacitor 19 that together constitute a standard Class D output LC filter. The interconnection of the inductor 18 and the capacitor 19 forms the output terminal 20 of the audio amplifier to which one or more loudspeakers may be connected. Parallel diodes 21 and 22 in parallel with the emitter-collector paths of the output transistors 7 and 8, respectively, serve to protect in Class D mode the output transistors 7 and 8 against the inductive load. The operational amplifier 1, the power output stage 6 and the LC-filter 18-19 constitute the signal path of the audio amplifier. The amplifier further comprises a feedback path 23 with an input terminal 24 connected to the output terminal 11 of the output stage 6 and an output terminal 25 connected to the inverting input terminal 3 of the operational amplifier 1.

The feedback path comprises two series connected resistors 26 and 27 between the input terminal 24 and the output terminal 25. The interconnection of these two resistors is connected to ground through a capacitor 28 and to a point 29 through a capacitor 30. A series arrangement of a resistor 31 and a capacitor 32 is connected between the output terminal 25 and ground. And a parallel arrangement of a resistor 33 and a capacitor 34 is connected between the output terminal 25 and the point 29. This point 29 is connected through a capacitor 35 to the grounded parallel arrangement of a resistor 36 and a switch transistor 37.

The output voltage Vₒ of the amplifier, present at terminal 20, is applied to a level detector 38 that controls the switch transistor 37. The switch transistor is open (cut off) at lower levels of the output voltage Vₒ and closed (conducting) at higher levels of this output voltage.

In an audio amplifier tested in practice the passive components had the following values:

| | | | |
|---|---|---|---|
| Resistor | 12 | 470 | Ω |
| | 13 | 1 | kΩ |
| | 14 | 1 | kΩ |
| | 15 | 33 | kΩ |
| | 16 | 33 | kΩ |
| | 26 | 47 | kΩ |
| | 27 | 47 | kΩ |
| | 31 | 4.7 | kΩ |
| | 33 | 270 | kΩ |
| | 36 | 470 | kΩ |
| Capacitor | 19 | 470 | nF |
| | 28 | 47 | pF |
| | 30 | 47 | pF |
| | 32 | 2.2 | μF |
| | 34 | 220 | pF |
| | 35 | 100 | nF |
| Inductor | 18 | 68 | μH |

The arrangement comprising the bipolar transistors 7-10 and the resistors 12-17 constitutes a linear power amplifier that, dependent on the value of these resistors may be biased to operate in Class B or preferably in Class AB. The resistor 17 allows adjusting the amplification of the stage. The addition of the parallel diodes 21 and 22 allow the power output stage 6 to operate in the switched Class D mode. The LC-filter 18-19 substantially attenuates in Class D the hinge switching frequency and its harmonics in the output signal of the amplifier and does not at all harm the Class AB/B operation.

For the audio frequency band of 20 Hz to 20 kHz the attenuation of the feedback path 23, (i.e. the amplification of the whole amplifier) is substantially determined by the resistors 26, 27 and 31. The capacitors 28, 30 and 34 are too small and the capacitors 32 and 35 are too large to have substantial influence in this frequency range.

At substantially higher frequencies the capacitors 28, 30 and 34 are responsible for a phase shift. However when the switch transistor 37 is cut off, this phase shift is not sufficient to cause the amplifier to oscillate with the result that the amplifier operates in the linear (Class AB or B) mode. On the other hand, when the switch transistor is conducting the capacitors 30 and 34 are grounded through the capacitor 35 and the transistor 37. This results in a phase shirt, which, together with the phase shift of the operational amplifier 1 at these frequencies, is sufficient to support oscillation of the amplifier. This oscillation results in a pulse train that is pulse-width modulated by the audio signal and whose frequency is also dependent on the audio signal.

The capacitor 35 plays an important role in avoiding that transients occur at the transition from one mode to the other. This capacitor keeps any DC-potential away from the switch and therefore prevents DC-flanks occurring when the transistor switches. The capacitor 32 ensures that the DC-transfer of the feedback path is equal to 1. Without this capacitor a DC-offset e.g. in the operational amplifier 1 would appear amplified at the output 20 with a correspondingly large DC-current in the loudspeaker.

The level detector 38 can have various implementations. For instance the output voltage Vₒ from the output terminal 20 may be applied to a double-sided rectifier and the rectified signal may be applied to a comparator where the rectified signal is compared with a predetermined reference voltage. The output of the comparator is fed to the switch transistor 37. The result is that the amplifier operates in Class D mode when the absolute value of the audio signal V0 is above the predetermined voltage and in Class AB when this absolute value is below the predetermined voltage. Thus all the zero-crossings of the audio signal are treated in Class AB. Of course, when the extreme value of the output voltage Vₒ remains below the predetermined voltage, the amplifier remains in Class AB all the time.

Alternatively, the rectifier may be a top-detector, which comprises a capacitor that is quickly charged when the output voltage Vₒ raises and slowly discharged when the voltage level falls. The amplifier switches into the Class D mode as soon as the audio signal V0 rises above a predetermined level set by the comparator, but it needs a substantial time for the amplifier to switch back to the linear mode when the audio signal has fallen below the predetermined level, resulting in switching back to the linear mode at another level, lower than the predetermined level. In this way the number of mode-switchings is substantially reduced and a form of hysteresis is introduced.

Additionally, the comparator of the level detector may comprise hysteresis with two comparator levels. The audio signal has to fall below a first comparator level for the amplifier to switch to the Class AB mode, and has to pass a second comparator level, higher than the first level, for the amplifier to switch to Class D.

It should be mentioned that the above-described embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “comprise” and its conjugations does not exclude the presence of elements or steps other than those stated in a claim. The article “a” or “an” preceding an element does not exclude the presence of a plurality of such elements. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measures cannot be used to advantage.

1. A dual mode audio amplifier comprising a single power output stage (6), having a linear operation in a first mode and a switched operation in a second mode, and mode switching means (37) for switching the power output stage (6) in the first mode if the audio signal is below a first level, and in the second mode if the audio signal is above a second level.

2. A dual mode audio amplifier as claimed in claim 1, wherein the mode switching means (37) are provided in a feedback path (23) of the dual mode audio amplifier.

3. A dual mode audio amplifier as claimed in claim 2, the feedback path (23) comprising low pass filtering means for substantially passing the audio frequency band and for phase shifting frequencies above said audio frequency band, the mode switching means (37) being arranged to change an amount of phase shift of said frequencies above the audio frequency band.

4. A dual mode audio amplifier as claimed in claim 2, the feedback path (23) comprising DC blocking means (35) to substantially prevent a DC-potential from building Lip across the mode switching means (37).

5. A dual mode audio amplifier as claimed in claim 2, wherein a transfer of the feedback path (23) is substantially lower than 1 for the audio frequency band, the transfer of the feedback path being substantially one for DC-voltage.
